(19) United States
(12) Patent Application Publication
(10) Pub. No.: US 2026/0247964 A1
(43) Pub. Date: Aug. 20, 2026

(54) HEAT DISSIPATION PACKAGE AND METHOD OF MANUFACTURING THE SAME

(71) Applicant: CHIPBOND TECHNOLOGY CORPORATION, Hsinchu City (TW)

(72) Inventors: Yung-Wei Hsieh, Hsinchu City (TW); Cheng-Hung Shih, Hsinchu County (TW); Chih-Hao Chiang, Hsinchu City (TW); Pai-Sheng Cheng, Hsinchu City (TW)

(21) Appl. No.: 19/468,017

(22) Filed: Feb. 3, 2026

(30) Foreign Application Priority Data
Feb. 20, 2025 (TW) 114106352

(51) Int. Cl. H10W 40/20; H10W 70/08; H10W 70/65; H10W 72/00; H10W 74/01; H10W 74/10; H10W 90/00

(52) U.S. Cl. CPC H10W 40/242; H10W 40/233; H10W 70/08; H10W 70/657; H10W 72/07338; H10W 74/014; H10W 74/114; H10W 90/736

(57) ABSTRACT

A method of manufacturing heat dissipation packages includes the steps as following. Heat dissipation layers each including a main portion and a carry portion are provided, the main portion has an outer surface and an inner surface, and the carry portion protrudes from the inner surface. An uncured thermally conductive material is provided on a carry surface of the carry portion and it can flow within the carry surface only. Electronic components are bonded to the uncured thermally conductive material to be connected to the heat dissipation layers. Owing to the uncured thermally conductive material is restricted to flow within the carry surface, it is able to prevent the electronic components from shifting caused by cohesion of the uncured thermally conductive material.

### CROSS-REFERENCE TO RELATED APPLICATIONS

This application claims priority to R.O.C Patent Application No. 114106352 filed Feb. 20, 2025, the disclosure of which is hereby incorporated by reference in its entirety.

### FIELD OF THE INVENTION

This invention relates to a heat dissipation package and its manufacturing method which can avoid electronic components bonded to heat dissipation layer from shifting caused by cohesion of uncured thermally conductive material.

### BACKGROUND OF THE INVENTION

Owing to integrated circuits have improved computing speed and reduced size, electronic components, such as chips, may generate high temperature heat to affect computing speed or damage electronic components. In order to lower temperature of the electronic components, heat dissipation structures (e.g. heat dissipation sheets) are usually adhered onto encapsulants or the electronic components via an adhesive for heat dissipation. Conventionally, the heat dissipation structure is adhered onto the encapsulant or the electronic component after packaging process, but it is not easy to align the heat dissipation structure, and alignment of the heat dissipation structure may slow down production efficiency.

### SUMMARY OF THE INVENTION

The object of the present invention is to provide a heat dissipation package and its manufacturing method. An uncured thermally conductive material is provided on a carry surface of a carry portion of a heat dissipation layer and restricted within the carry surface such that shifting of an electronic component caused by cohesion of the uncured thermally conductive material can be suppressed as the electronic component is bonded to the heat dissipation layer via the uncured thermally conductive material.

A method of manufacturing a heat dissipation package of the present invention includes the steps as following. Heat dissipation layers are provided, each of them includes a main portion and a carry portion, the main portion has an outer surface and an inner surface, a first area and a second area are defined on the inner surface, the carry portion is located on and protrudes from the first area and exposes the second area. An uncured thermally conductive material is provided on a carry surface of the carry portion and it is restricted to flow within the carry surface. Electronic components are bonded to the uncured thermally conductive material to connect together. An encapsulant is provided to cover the heat dissipation layers and the electronic components, heat dissipation packages are obtained and each of them includes one of the heat dissipation layers and one of the electronic components. The encapsulant is cut to separate the heat dissipation packages.

A heat dissipation package of the present invention includes a heat dissipation layer, a thermally conductive material, an electronic component and an encapsulation element. The heat dissipation layer includes a main portion and a carry portion, the main portion has an outer surface and an inner surface, and a first area and a second area are defined on the inner surface. The carry portion is located on and protrudes from the first area. The thermally conductive material is provided on a carry surface of the carry portion and restricted to flow within the carry surface before curing. The electronic component is bonded to the thermally conductive material. The encapsulation element covers the heat dissipation layer and the electronic component and not cover the outer surface of the main portion.

Owing to the carry portion located on the first area, the uncured thermally conductive material is restricted to flow within the carry surface of the carry portion. The present invention can prevent the electronic components from shifting resulted from cohesion of the uncured thermally conductive material as bonding the electronic components to the heat dissipation layers.

### BRIEF DESCRIPTION OF DRAWINGS

FIGS. 1 to 8 are cross-section view diagrams illustrating a method of manufacturing heat dissipation packages in accordance with one embodiment of the present invention.

FIG. 9 is a cross-section view diagram illustrating a heat dissipation package in accordance with one embodiment of the present invention.

### DETAILED DESCRIPTION OF THE INVENTION

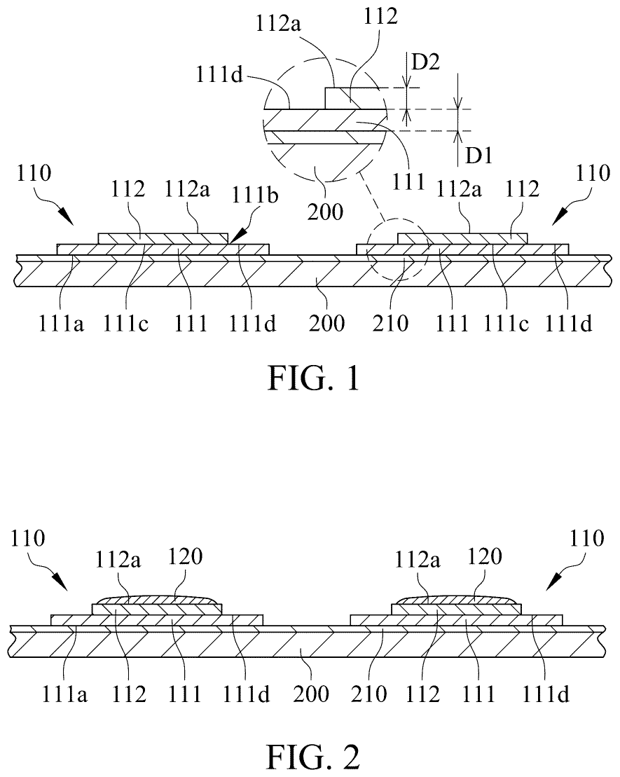

With reference to FIGS. 1 to 9, a plurality of heat dissipation packages 100 can be obtained by a method of the present invention mentioned below. Referring to FIG. 1, a plurality of heat dissipation layers 110 are provided on a carrier 200 and each includes a main portion 111 and a carry portion 112. In this embodiment, a release film 210 is coated on the carrier 200, and the heat dissipation layers 110 are adhered onto the carrier 200 via the release film 210. The carrier 200 may be made of glass, ceramic or other materials, and the heat dissipation layers 110 may be made of copper or other thermally conductive materials. The heat dissipation layers 110 can be formed on the carrier 200 through plating or etching process. In the etching process, a thermally conductive laminate is etched to become the heat dissipation layers 110.

With reference to FIG. 1, the main portion 111 of each of the heat dissipation layers 110 has an outer surface 111a and an inner surface 111b. A first area 111c and a second area 111d are defined on the inner surface 111b, the second area 111d is located outside the first area 111c, and preferably, the second area 111d surrounds the first area 111c.

With reference to FIG. 1, the carry portion 112 of each of the heat dissipation layers 110 is located on and protrudes from the first area 111c, and the carry portion 112 exposes the second area 111d. Each of the heat dissipation layers 110 is disposed on the carrier 200 via its outer surface 111a, and in this embodiment, each of the heat dissipation layers 110 is attached onto the release film 210 via its outer surface 111a. A first thickness D1 of the main portion 111 is greater than or equal to a second thickness D2 of the carry portion 112, and the difference between the first thickness D1 and the second thickness D2 is greater than or equal to 0 μm and less than or equal to 35 μm so as to avoid warpage of the heat dissipation layers 110. Preferably, the first thickness D1 is greater than or equal to 5 μm and less than or equal to 40 μm, and the second thickness D2 is greater than or equal to 5 μm and less than or equal to 10 μm.

With reference to FIG. 2, next, an uncured thermally conductive material 120 is provided on a carry surface 112a of the carry portion 112. The uncured thermally conductive material 120 can be tin (Sn) or other thermally conductive materials, and it can be cured to become solid. Owing to the carry portion 112 protrudes from the first area 111c, the uncured thermally conductive material 120 is restricted on the carry surface 112a of the carry portion 112.

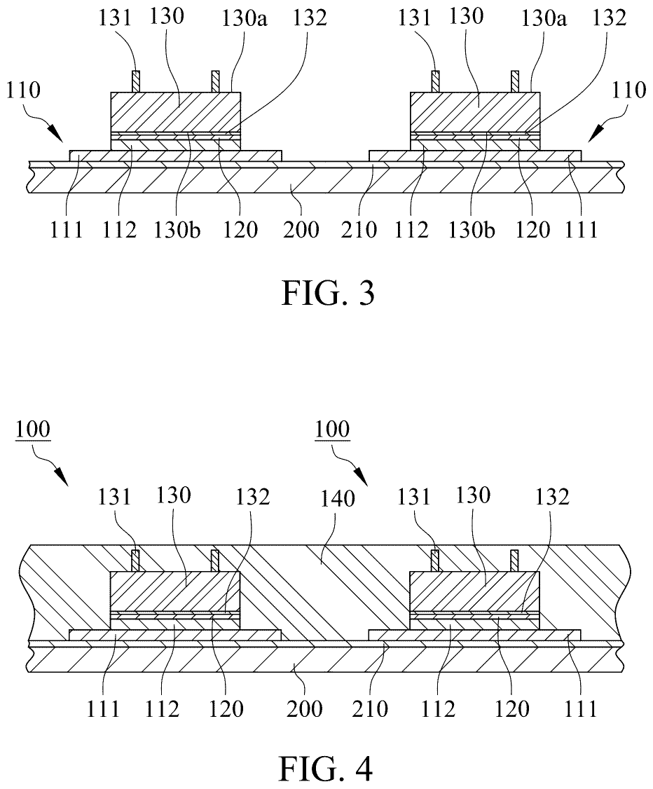

With reference to FIG. 3, a plurality of electronic components 130 are bonded to the uncured thermally conductive material 120 on each of the heat dissipation layers 110, respectively, such that each of the electronic components 130 is connected to one of the heat dissipation layers 110. During bonding the electronic components 130 to the heat dissipation layers 110, cohesion of the uncured thermally conductive material 120 which is restricted to flow within the carry surface 112a of the carry portion 112 will not cause shifting of the electronic components 130.

With reference to FIG. 3, in this embodiment, each of the electronic components 130 includes a plurality of bonding elements 131 which are arranged on an active surface 130a of each of the electronic components 130. The bonding elements 131 may be bonding pillars or bonding pads. Preferably, each of the electronic components 130 further includes a back-side metallization (BSM) 132 which is formed on a back surface 130b of each of the electronic components 130, and each of the electronic components 130 is bonded to the uncured thermally conductive material 120 via the back-side metallization 132.

With reference to FIG. 4, an encapsulant 140 is provided on the carrier 200 and covers the heat dissipation layers 110 and the electronic components 130 to obtain the heat dissipation packages 100 which are connected to each other. Each of the heat dissipation packages 100 includes at least one heat dissipation layer 110 and at least one electronic component 130.

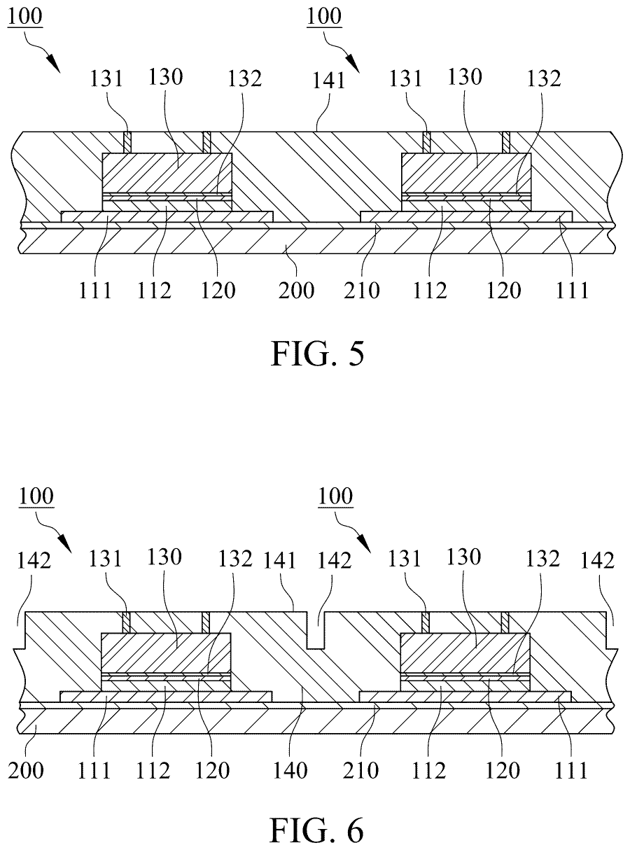

With reference to FIG. 5, next, the encapsulant 140 is grinded to allow the bonding elements 131 to be visible from an exposed surface 141 of the encapsulant 140, and the encapsulant 140 is cleaned to remove contaminants or oxidation layers on the bonding elements 131. In another embodiment, the bonding elements 131 are visible from the exposed surface 141 after forming the encapsulant 140 on the carrier 200 so the encapsulant 140 is not required to be grinded.

With reference to FIG. 6, a plurality of grooves 142 are formed on the exposed surface 141 of the encapsulant 140, and each of the grooves 142 is located between the adjacent heat dissipation packages 100.

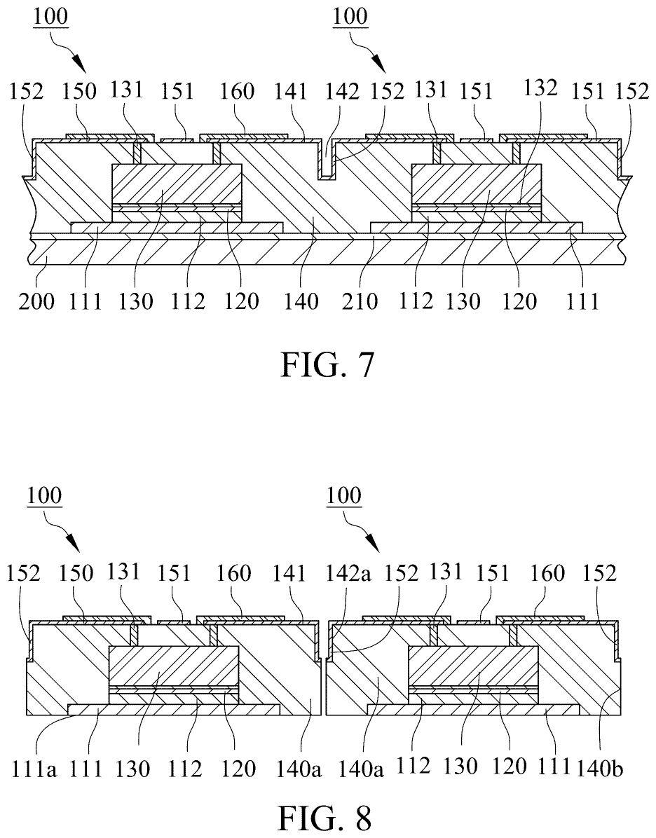

With reference to FIG. 7, a redistribution layer (RDL) 150 is formed on the exposed surface 141 and in the grooves 142. The RDL 150 is electrically connected to the electronic components 130, and in this embodiment, the RDL 150 is electrically connected to the bonding elements 131 of each of the electronic components 130. The RDL 150 includes a plurality of conductive pads 151 located on the exposed surface 141 and a plurality of side pads 152 located in the grooves 142, respectively. Next, a plurality of protection layers 160 are formed on the RDL 150 and they don't cover the conductive pads 151 and the side pads 152. Preferably, a bonding layer (not shown, such as gold layer) can be formed on the conductive pads 151 and the side pads 152. In different embodiments, multiple RDLs 150 and multiple protection layers 160 can be formed on the exposed surface 141 alternately.

With reference to FIG. 8, the carrier 200 and the release film 210 are removed to expose the outer surface 111a of the main portion 111, and the encapsulant 140 and the RDL 150 are cut along the grooves 142 to separate the heat dissipation packages 100. After cutting, the encapsulant 140 becomes a plurality of encapsulation elements 140a covering the heat dissipation layers 110 and the electronic components 130, each of the grooves 142 becomes a half groove 142a located on a lateral surface 140b of each of the encapsulation elements 140a, and the side pad 152 is retained in the half groove 142a.

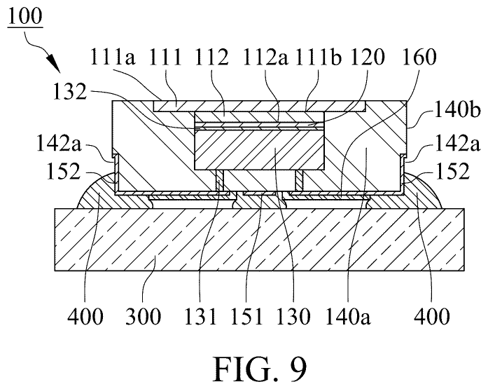

With reference to FIG. 9, each of the heat dissipation packages 100 manufactured by the method mentioned above includes the heat dissipation layer 110, the thermally conductive material 120, the electronic component 130 and the encapsulation element 140a. The heat dissipation layer 110 includes the main portion 111 and the carry portion 112 which protrudes from the first area 111c of the inner surface 111b and exposes the second area 111d of the inner surface 111b. The thermally conductive material 120 is restricted on the carry surface 112a of the carry portion 112 before being cured. The electronic component 130 is bonded to the thermally conductive material 120, and shifting of the electronic component 130 caused by cohesion of the uncured thermally conductive material 120 can be suppressed because the uncured thermally conductive material 120 is restricted to flow within the carry surface 112a. The encapsulation element 140a covers the heat dissipation layer 110 and the electronic component 130 and not cover the outer surface 111a of the main portion 111. The half groove 142a is located on the lateral surface 140b of the encapsulation element 140a.

In this embodiment, the heat dissipation package 100 further includes the RDL 150 electrically connected to the electronic component 130 and the protection layer 160 covering the RDL 150. The RDL 150 includes the conductive pads 151 located on the encapsulation element 140a and the side pad 152 located in the half groove 142a, and the conductive pads 151 and the side pad 152 are visible from the protection layer 160.

With reference to FIG. 9, while the heat dissipation package 100 is bonded to a circuit board 300 by a bonding element 400, e.g. solder ball, the side pad 152 located in the half groove 142a can increase the contacting area between the heat dissipation package 100 and the bonding element 400 to avoid the heat dissipation package 100 from separating from the circuit board 300.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A method of manufacturing heat dissipation packages comprising:
providing a plurality of heat dissipation layers, each of the plurality of heat dissipation layers includes a main portion and a carry portion, the main portion has an outer surface and an inner surface, a first area and a second area are defined on the inner surface, the carry portion protrudes from the first area and exposes the second area;
providing an uncured thermally conductive material on a carry surface of the carry portion of each of the plurality of heat dissipation layers, wherein the uncured thermally conductive material is restricted to flow within the carry surface;
bonding a plurality of electronic components to the uncured thermally conductive material on the carry surface of the carry portion of each of the plurality of heat dissipation layers, each of the plurality of electronic components is connected to one of the plurality of heat dissipation layers;
forming an encapsulant, the plurality of heat dissipation layers and the plurality of electronic components are covered by the encapsulant to become a plurality of heat dissipation packages which are connected to one another, each of the plurality of heat dissipation packages includes one of the plurality of heat dissipation layers and one of the plurality of electronic components; and
cutting the encapsulant to separate the plurality of heat dissipation packages.

2. The method in accordance with claim 1, wherein the second area is located outside the first area.

3. The method in accordance with claim 2, wherein the second area surrounds the first area.

4. The method in accordance with claim 1, wherein a first thickness of the main portion is greater than or equal to a second thickness of the carry portion.

5. The method in accordance with claim 4, wherein a difference between the first and second thicknesses is greater than or equal to 0 μm and less than or equal to 35 μm.

6. The method in accordance with claim 5, wherein the first thickness is greater than or equal to 5 μm and less than or equal to 40 μm, and the second thickness is greater than or equal to 5 μm and less than or equal to 10 μm.

7. The method in accordance with claim 1, wherein each of the plurality of electronic components includes a back-side metallization which is formed on a back surface of each of the plurality of electronic components, and each of the plurality of electronic components is bonded to the uncured thermally conductive material via the back-side metallization.

8. The method in accordance with claim 1, wherein after forming the encapsulant, a plurality of grooves are formed on an exposed surface of the encapsulant, and each of the plurality of grooves is located between the adjacent heat dissipation packages.

9. The method in accordance with claim 8, wherein after forming the plurality of grooves, a redistribution layer is formed on the exposed surface of the encapsulant and formed in the plurality of grooves and a protection layer is formed on the redistribution layer, the redistribution layer is electrically connected to the plurality of electronic components and includes a plurality of conductive pads and a plurality of side pads, the plurality of conductive pads are located on the exposed surface of the encapsulant, each of the plurality of side pads is located in one of the plurality of grooves, and the plurality of conductive pads and the plurality of side pads are visible from the protection layer.

10. The method in accordance with claim 9, wherein after forming the redistribution layer and the protection layer, the encapsulant is cut along the plurality of grooves to become a plurality of encapsulation elements and each of the plurality of grooves becomes a half groove located on a lateral surface of each of the plurality of encapsulation elements, each of the plurality of encapsulation elements covers one of the plurality of heat dissipation layers and one of the plurality of electronic components, and each of the plurality of side pads is retained in the half groove.

11. The method in accordance with claim 9, wherein each of the plurality of electronic components includes a plurality of bonding elements which are visible from the exposed surface of the encapsulant and electrically connected to the redistribution layer.

12. The method in accordance with claim 11, wherein before forming the plurality of grooves, the encapsulant is grinded to allow the plurality of bonding elements to be visible from the exposed surface of the encapsulant.

13. The method in accordance with claim 1, wherein each of the plurality of heat dissipation layers is disposed on a carrier via the outer surface, and the carrier is removed before cutting the encapsulant.

14. A heat dissipation package comprising:
a heat dissipation layer including a main portion and a carry portion, the main portion has an outer surface and an inner surface, a first area and a second area are defined on the inner surface, the carry portion protrudes from the first area and exposes the second area;
a thermally conductive material provided on a carry surface of the carry portion, wherein the thermally conductive material is restricted to flow within the carry surface before being cured;
an electronic component bonded to the thermally conductive material; and
an encapsulation element covering the heat dissipation layer and the electronic component and exposing the outer surface of the main portion.

15. The heat dissipation package in accordance with claim 14, wherein the second area is located outside the first area.

16. The heat dissipation package in accordance with claim 14, wherein the second area surrounds the first area.

17. The heat dissipation package in accordance with claim 14, wherein a first thickness of the main portion is greater than or equal to a second thickness of the carry portion.

18. The heat dissipation package in accordance with claim 17, wherein a difference between the first and second thicknesses is greater than or equal to 0 μm and less than or equal to 35 μm.

19. The heat dissipation package in accordance with claim 18, wherein the first thickness is greater than or equal to 5 μm and less than or equal to 40 μm, and the second thickness is greater than or equal to 5 μm and less than or equal to 10 μm.

20. The heat dissipation package in accordance with claim 14 further comprising a redistribution layer and a protection layer, wherein the redistribution layer is electrically connected to the electronic component and covered by the protection layer, there is a half groove on a lateral surface of the encapsulation element, the redistribution layer includes a plurality of conductive pads located on the encapsulation element and a side pad located in the half groove, the plurality of conductive pads and the side pad are visible from the protection layer.
